(19) United States
(12) Patent Application Publication
(10) Pub. No.: US 2026/0279429 A1
(43) Pub. Date: Sep. 17, 2026

(54) STORAGE DEVICE, CONTROLLER AND MEMORY DEVICE

(71) Applicant: SK hynix Inc., Icheon-si (KR)

(72) Inventors: Dong Young SEO, Icheon-si (KR); Hoon CHO, Icheon-si (KR); Myeong Woon JEON, Icheon-si (KR)

(21) Appl. No.: 19/327,773

(22) Filed: Sep. 12, 2025

(30) Foreign Application Priority Data
Mar. 11, 2025 (KR) 10-2025-0031543

(51) Int. Cl. G11C 11/406; G11C 11/4076; G11C 29/52

(52) U.S. Cl. CPC G11C 11/40622; G11C 11/4076; G11C 29/52

(57) ABSTRACT

A storage device compares a first error bit number of a first word line included in a first weak word line group of a target memory block during a first period with a preset first reference value, compares the difference between a second error bit number of a second word line included in a strong word line group of the target memory block and the first reference value with a preset second reference value, sets a movement range of data of the target memory block on the basis of a result of comparing the difference with the second reference value, and moves the data to a preset space, whereby it is possible to efficiently perform a refresh operation on a memory block.

### CROSS-REFERENCE TO RELATED APPLICATION

The present application claims priority under 35 U.S.C. §119(a) to Korean Patent Application No. 10-2025-0031543 filed in the Korean Intellectual Property Office on Mar. 11, 2025, which is incorporated herein by reference in its entirety.

### BACKGROUND

### 1. Technical Field

Embodiments of the present disclosure relate to a controller, a memory device and a storage device.

### 2. Related Art

A storage device may include at least one memory that stores data. The storage device may include a controller that controls the operation of the at least one memory.

The controller may control a memory device (e.g., volatile memory/nonvolatile memory). For example, by setting a range within a memory block included in the memory device, the controller may execute or control an operation of moving data included in memory.

A memory device may include not only a device that stores data on a magnetic disk, such as a hard disk drive (HDD), but also a device that stores data in a nonvolatile memory, such as a solid state drive (SSD), a universal flash storage (UFS) device and an embedded MMC (eMMC) device. For example, in order to ensure the reliability of data stored in a memory device, a refresh operation may be performed in which stored data is moved to a set space or is rewritten.

### SUMMARY

Objects of embodiments of the disclosure are not limited to those set forth herein, and other objects that are not mentioned will be apparent to one of ordinary skill in the art from the following description.

Embodiments of the present disclosure are directed to providing measures for determining criteria for an area within a memory block that requires a refresh, thereby preventing a shortened lifespan of a memory device due to performance of unnecessary refresh operations.

In an embodiment, a storage device may include: a memory including a plurality of memory blocks each of which includes a plurality of word lines; and a controller configured to compare a first error bit number of a first word line included in a first weak word line group of a target memory block during a first period with a preset first reference value, compare the difference between a second error bit number of a second word line included in a strong word line group of the target memory block and the first reference value with a preset second reference value, and set a movement range of data of the target memory block to be moved to a preset space on the basis of a result of comparing the difference with the second reference value.

In an embodiment, a controller may include: an error bit search unit configured to check a first error bit number of a first word line included in a first weak word line group of a target memory block located outside during a first period, and check, on the basis of a comparison result between the first error bit number and a preset first reference value, a second error bit number of a second word line included in a strong word line group of the target memory block; and a movement range determination unit configured to compare the first error bit number with the first reference value, compare the difference between the second error bit number and the first reference value with a preset second reference value, and set, on the basis of a comparison result between the difference and the second reference value, a movement range of data of the target memory block to be moved to a preset space.

In an embodiment, a memory device may include: a first memory block including a target memory block that includes a first weak word line group and a strong word line group; and a second memory block to which data of the target memory block is to be moved, wherein a movement range for the data of the target memory block to be moved to the second memory block is determined on the basis of a first comparison result in which a first error bit number of a first word line included in the first weak word line group of the target memory block during a first period is compared with a preset first reference value and a second comparison result in which the difference between a second error bit number of a second word line included in the strong word line group of the target memory block and the first reference value is compared with a preset second reference value.

According to the embodiments of the present disclosure, it is possible to suggest criteria for determining an area within a memory block that requires a refresh operation, thereby solving a problem in which the lifespan of a memory device is shortened due to excessive refresh operations.

The effects of the disclosure are not limited to the foregoing objects, and other effects will be apparent to one of ordinary skill in the art from the following detailed description.

### BRIEF DESCRIPTION OF THE DRAWINGS

The disclosure will be more fully understood from the following detailed description and the accompanying drawings, which are provided for illustration only and are not intended to limit the disclosure.

FIG. 1 is a diagram illustrating a schematic configuration of a storage device according to embodiments of the present disclosure.

FIG. 2 is a diagram illustrating a schematic configuration of a memory device according to embodiments of the present disclosure.

FIG. 3 is a diagram illustrating a schematic configuration of a controller according to embodiments of the present disclosure.

FIG. 4 is a diagram illustrating a configuration of a target memory block on which a refresh operation is executed according to embodiments of the present disclosure.

FIG. 5 is a flowchart showing a process of determining whether to perform a refresh operation on a target memory block according to embodiments of the present disclosure.

FIG. 6 is a diagram illustrating a configuration of a target memory block on which a refresh operation is executed according to other embodiments of the present disclosure.

FIG. 7 is a flowchart showing a process of determining a range of a target memory block in which a refresh operation is to be performed according to other embodiments of the present disclosure.

FIG. 8 is a diagram showing a refresh operation performed on a target memory block according to still other embodiments of the present disclosure.

### DETAILED DESCRIPTION

In the following description of examples or embodiments of the present disclosure, reference will be made to the accompanying drawings in which it is shown by way of illustration specific examples or embodiments that can be implemented, and in which the same reference numerals and signs can be used to designate the same or like components even when they are shown in different accompanying drawings. Further, in the following description of examples or embodiments of the present disclosure, detailed descriptions of well-known functions and components incorporated herein will be omitted when it is determined that the description may make the subject matter in some embodiments of the present disclosure more unclear. The terms such as “including”, “having”, “containing”, “constituting” “made up of”, and “formed of” used herein are generally intended to allow other components to be added unless the terms are used with the term “only”. As used herein, singular forms are intended to include plural forms unless the context clearly indicates otherwise.

Terms, such as “first”, “second”, “A”, “B”, “(A)”, or “(B)” may be used herein to describe elements of the present disclosure. Each of these terms is not used to define essence, order, sequence, or number of elements etc., but is used merely to distinguish the corresponding element from other elements.

When it is mentioned that a first element "is connected or coupled to", “contacts or overlaps” etc. a second element, it should be interpreted that, not only can the first element “be directly connected or coupled to” or “directly contact or overlap” the second element, but a third element can also be "interposed" between the first and second elements, or the first and second elements can "be connected or coupled to", “contact or overlap”, etc. each other via a fourth element. Here, the second element may be included in at least one of two or more elements that "are connected or coupled to", “contact or overlap”, etc. each other.

When time relative terms, such as "after," "subsequent to," "next," "before," and the like, are used to describe processes or operations of elements or configurations, or flows or steps in operating, processing, or manufacturing methods, these terms may be used to describe non-consecutive or non-sequential processes or operations unless the term "directly" or "immediately" is used together.

In addition, when any dimensions, relative sizes etc. are mentioned, it should be considered that numerical values for an elements or features, or corresponding information (e.g., level, range, etc.) include a tolerance range or error margin that may be caused by various factors (e.g., process factors, internal or external impact, noise, etc.) even when a relevant description is not specified. Further, the term “may” fully encompasses all the meanings of the term “can”.

Hereinafter, various embodiments of the present disclosure will be described in detail with reference to accompanying drawings.

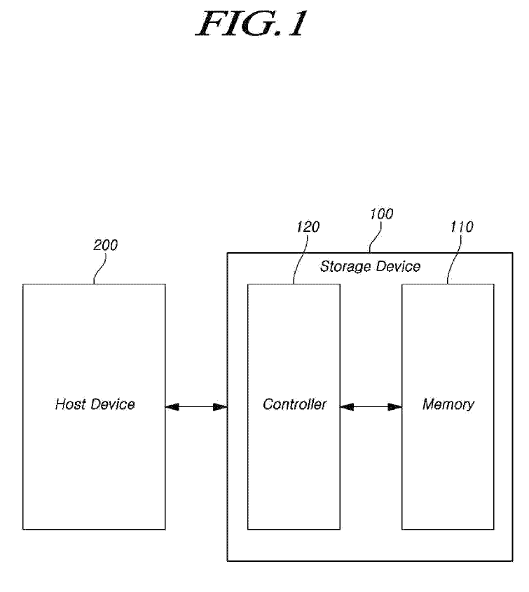

FIG. 1 is a diagram illustrating a schematic configuration of a storage device according to embodiments of the present disclosure.

Referring to FIG. 1, a storage device 100 may include at least one memory 110. The storage device 100 may include a controller 120 that controls the operation of the memory 110.

The memory 110 may be, for example, volatile memory such as DRAM, SDRAM, DDR SDRAM and LPDDR SDRAM, but embodiments of the present disclosure are not limited thereto. The memory 110 may be nonvolatile memory such as NAND flash memory, 3D NAND flash memory and NOR flash memory. Some parts of the memory 110 included in the storage device 100 may be volatile memory, while other parts of the memory 110 may be nonvolatile memory.

In addition, the memory 110 may be one of various types of memory such as resistive RAM, phase change memory, magnetoresistive memory, ferroelectric memory or spin transfer torque memory. The memory 110 may be processing-in-memory that includes a computation function or a data processing function.

The memory 110 may include a plurality of memory cells that store data. For example, a memory cell may be a single-level cell that stores 1-bit data. Alternatively, the memory cell may be a multi-level cell that stores 2 bits of data or a triple-level cell that stores 3 bits of data. The memory cell may also store 4 or more bits of data, or may operate as a memory cell that changes type. For example, a memory cell may store data while operating as a single-level cell, or the same memory cell may store data while operating as a triple-level cell. At least two memory cells may constitute a unit storage area such as one page.

The controller 120 may receive a command from the outside (i.e., from an external device), and may control the operation of the memory 110 on the basis of the received command. In addition, the controller 120 may control the operation of the memory 110 on the basis of an internally generated command. In the present specification, a command that the controller 120 receives from the outside may be referred to as an external command, and a command that is generated inside the controller 120 may be referred to as an internal command.

The controller 120 may control the operation of the memory 110 on the basis of the external command or the internal command. For example, the controller 120 may control an operation of writing data to the memory 110. The controller 120 may control an operation of reading data written to the memory 110. Data may be transmitted and received between the controller 120 and the memory 110. Additionally, the controller 120 may control the entirety or a part of data included in the memory 110 to be moved to a preset space. The preset space may include a specific memory block in the memory 110.

Depending on the type of the memory 110, the controller 120 may control a data preservation operation (e.g., a refresh operation or a patrol scrub operation) or an erase operation on data written to the memory 110.

In order to maintain and improve the operational performance of the storage device 100, the controller 120 may perform a background operation related with the memory 110 on the basis of an external command received from an external host device 200 or on the basis of an internal command.

The background operation may include at least one among, for example, garbage collection, wear leveling, read reclaim and bad block management operations. Through control of the background operation, the controller 120 may improve the operational performance of the storage device 100 or prevent the operational performance of the storage device 100 from deteriorating.

The controller 120 may control the operation of the memory 110 on the basis of a command received from the host device 200. The controller 120 may provide the host device 200 with a processing result according to an operation corresponding to the command. The controller 120 may transmit data or a response signal to the host device 200.

For example, the host device 200 may be a computer, an ultra mobile PC (UMPC), a workstation, a personal digital assistant (PDA), a tablet, a mobile phone, a smartphone, an e-book, a portable multimedia player (PMP), a portable game player, a navigation device, a black box, a digital camera, a digital multimedia broadcasting (DMB) player, a smart television, a digital audio recorder, a digital audio player, a digital picture recorder, a digital picture player, a digital video recorder, a digital video player, a storage configuring a data center, one of various electronic devices configuring a home network, one of various electronic devices configuring a telematics network, a radio frequency identification (RFID) device, a mobility device (e.g., a vehicle, a robot or a drone) capable of traveling under human control or autonomous driving, etc. Alternatively, the host device 200 may be a virtual/augmented reality device that provides a 2D or 3D virtual reality image or augmented reality image. In addition to the examples described above, the host device 200 may be any one of various electronic devices each of which requires a storage device 100 capable of storing data.

The host device 200 may include at least one operating system. The operating system may manage and control overall functions and operations of the host device 200, and may control the interoperation between the host device 200 and the storage device 100. The operating system may be classified into a general operating system and a mobile operating system depending on the mobility of the host device 200.

The controller 120 and the host device 200 may be devices that are separated from each other. The controller 120 and the host device 200 may be implemented by being incorporated as one device. Alternatively, a partial configuration or function of the controller 120 may be implemented by being included in the host device 200. Below, for the sake of convenience in explanation, examples describe a controller 120 and the host device 200 as devices that are separated from each other.

The storage device 100 may further include a working memory to provide a buffer that is used when the controller 120 controls an operation.

The working memory may be, for example, volatile memory such as SRAM and DRAM, but embodiments are not limited thereto. The working memory may be located outside the controller 120 or may be located inside the controller 120.

The controller 120 may control various operations of the memory 110 using the working memory. For example, the controller 120 may load data representing the correspondence relationship between a logical address (a logical block address or a logical page number) indicated by the host device 200 and a physical address (a physical block address or a virtual page number) of the memory 110 into the working memory, and may perform a write operation or a read operation.

The controller 120 may perform control of various operations by loading the entirety of data into the working memory, or may perform control by loading only a part of data into the working memory.

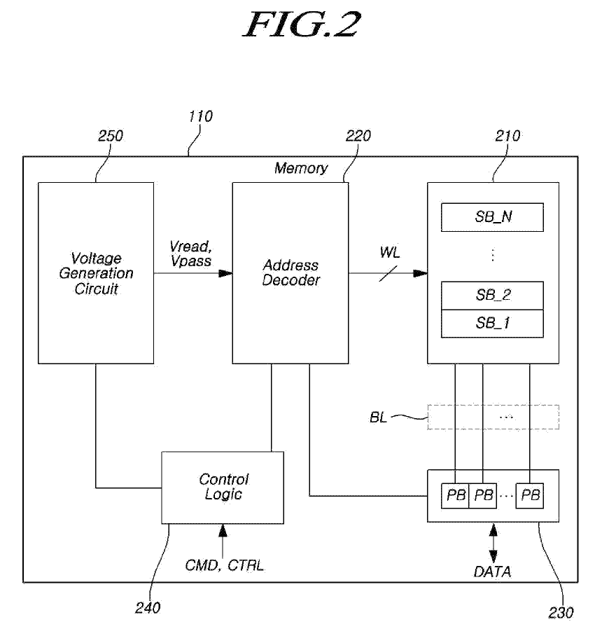

FIG. 2 is a diagram illustrating a schematic configuration of a memory device according to embodiments of the present disclosure.

Referring to FIG. 2, a memory 110 according to embodiments of the present disclosure may include a memory cell array 210, an address decoder 220, a read and write circuit 230, a control logic 240, and a voltage generation circuit 250.

The memory cell array 210 of the present disclosure may include an n number of storage blocks SB_1, SB_2, …, SB_n. In the present disclosure, storage blocks may be referred to as memory blocks. The storage block SB_1 may be referred to as a first memory block, and the storage block SB_2 may be referred to as a second memory block.

In the plurality of memory blocks, a plurality of word lines WL and a plurality of bit lines BL may be disposed, and a plurality of memory cells (MC) may be arranged. In addition, in the plurality of memory blocks, a word line group that includes at least one word line among the plurality of word lines may be included.

Two or more memory cells included in each of the plurality of memory blocks may constitute one page, which is a unit storage area. Each of the plurality of memory blocks may be a block that includes a plurality of pages.

The word line group described above may be classified into any one of a weak word line group, a normal word line group and a strong word line group according to preset criteria. The preset criteria may include classifying a weak word line group, a normal word line group and a strong word line group in descending order of the sum of the numbers of error bits detected in each word line group. According to criteria to be set, two or more weak word line groups and two or more strong word line groups may be classified.

The plurality of memory blocks may be connected to the address decoder 220 through the plurality of word lines. The plurality of memory blocks may be connected to the read and write circuits 230 through the plurality of bit lines.

Each of the plurality of memory blocks may include a plurality of memory cells. For example, the plurality of memory cells may be nonvolatile memory cells, and may be composed of nonvolatile memory cells that have a vertical channel structure.

In some embodiments, the memory cell array 210 may be configured as a memory cell array with a two-dimensional structure, and in other embodiments, may be configured as a memory cell array with a three-dimensional structure.

Each of the plurality of memory cells included in the memory cell array 210 may store at least 1 bit of data.

For example, each of the plurality of memory cells included in the memory cell array 210 may be a single-level cell (SLC) that stores 1 bit of data.

In another example, each of the plurality of memory cells included in the memory cell array 210 may be a multi-level cell (MLC) that stores 2 bits of data.

In yet another example, each of the plurality of memory cells included in the memory cell array 210 may be a triple-level cell (TLC) that stores 3 bits of data.

In still another example, each of the plurality of memory cells included in the memory cell array 210 may be a quad-level cell (QLC) that stores 4 bits of data.

In a further example, the memory cell array 210 may include a plurality of memory cells each of which stores 5 or more bits of data.

According to FIG. 2, the address decoder 220, the read and write circuit 230, the control logic 240 and the voltage generation circuit 250 may operate as a peripheral circuit that drives the memory cell array 210.

The address decoder 220 may be connected to the memory cell array 210 through the plurality of word lines.

The address decoder 220 may be configured to operate in response to control of the control logic 240.

The address decoder 220 may receive an address through an input/output buffer in the memory 110. The address decoder 220 may be configured to decode a block address in the received address. The address decoder 220 may select at least one memory block according to the decoded block address.

The address decoder 220 may receive a read voltage Vread and a pass voltage Vpass from the voltage generation circuit 250.

In an operation of applying a read voltage during a read operation, the address decoder 220 may apply the read voltage Vread to a selected word line WL in a selected memory block, and may apply the pass voltage Vpass to remaining unselected word lines WL.

In a program verify operation, the address decoder 220 may apply a verify voltage generated in the voltage generation circuit 250 to a selected word line WL in a selected memory block, and may apply the pass voltage Vpass to remaining unselected word lines WL.

The address decoder 220 may be configured to decode a column address in the received address. The address decoder 220 may transmit the decoded column address to the read and write circuit 230.

A read operation and a program operation of the memory 110 may be performed in the unit of a page. An address received when each of the read operation and the program operation is requested may include at least one of a block address, a row address and a column address.

The address decoder 220 may select one memory block and one word line according to the block address and the row address. The column address may be decoded by the address decoder 220, and the decoded column address may be provided to the read and write circuit 230.

The address decoder 220 may include at least one of a block decoder, a row decoder, a column decoder and an address buffer.

The read and write circuit 230 may include a plurality of page buffers PB. The read and write circuit 230 may operate as a read circuit in a read operation of the memory cell array 210, and may operate as a write circuit in a write operation of the memory cell array 210.

The read and write circuit 230 may also be referred to as a page buffer circuit or a data register circuit that includes a plurality of page buffers. The read and write circuit 230 may include a data buffer that takes charge of a data processing function, and may additionally include a cache buffer that takes charge of a caching function.

The plurality of page buffers may be connected to the memory cell array 210 through the plurality of bit lines. In order to sense threshold voltages (Vth) of memory cells in a read operation and a program verify operation, the plurality of page buffers may continuously supply sensing current to bit lines connected to the memory cells, and may latch sensing data by sensing, through sensing nodes, changing amounts of current flowing according to programmed states of the corresponding memory cells.

The read and write circuit 230 may operate in response to page buffer control signals output from the control logic 240.

In a read operation, the read and write circuit 230 may temporarily store read data by sensing data of memory cells, and then, may output data DATA to the input/output buffer of the memory 110. As an example embodiment, the read and write circuit 230 may include a column select circuit, etc. in addition to the page buffers or page registers.

The control logic 240 may be connected to the address decoder 220, the read and write circuit 230 and the voltage generation circuit 250. The control logic 240 may receive a command CMD and a control signal CTRL through the input/output buffer of the memory 110.

The control logic 240 may be configured to control overall operations of the memory 110 in response to the control signal CTRL. The control logic 240 may output control signals for adjusting the precharge potential levels of the sensing nodes of the plurality of page buffers.

The control logic 240 may control the read and write circuit 230 to perform a read operation of the memory cell array 210. The voltage generation circuit 250 may generate the read voltage Vread and the pass voltage Vpass to be used in a read operation, in response to a voltage generation circuit control signal output from the control logic 240.

Each of the memory blocks of the memory 110 described above may be composed of a plurality of pages corresponding to a plurality of word lines and a plurality of strings corresponding to a plurality of bit lines.

In each memory block, a plurality of word lines and a plurality of bit lines may be disposed to intersect each other. For example, each of the plurality of word lines may be disposed in a row direction, and each of the plurality of bit lines may be disposed in a column direction. In another example, each of the plurality of word lines may be disposed in the column direction, and each of the plurality of bit lines may be disposed in the row direction.

Each memory cell that is connected to one of the plurality of word lines and one of the plurality of bit lines may be defined. A transistor may be disposed in each memory cell.

For example, the transistor disposed in a memory cell may include a drain, a source and a gate. The drain (or the source) of the transistor may be connected to a corresponding bit line directly or via another transistor. The source (or the drain) of the transistor may be connected to a source line (which may be the ground) directly or via another transistor. The gate of the transistor may include a floating gate that is surrounded by an insulator and a control gate to which a gate voltage is applied from a word line.

In each memory block, a first select line (also referred to as a source select line or a drain select line) may be additionally disposed outside a first outermost word line of two outermost word lines that is more adjacent to the read and write circuit 230, and a second select line (also referred to as a drain select line or a source select line) may be additionally disposed outside a second outermost word line of the two outermost word lines.

In some embodiments, at least one dummy word line may be additionally disposed between the first outermost word line and the first select line. At least one dummy word line may also be additionally disposed between the second outermost word line and the second select line.

Memory blocks may store user data according to a request from the host device 200. Some of the memory blocks may store metadata including various information used for the operation of the memory 110. Alternatively, metadata may be stored in a storage area separate from the memory blocks that store user data.

A read operation and a program operation (a write operation) of the memory block described above may be performed by the unit of a page, and an erase operation may be performed by the unit of a memory block.

A movement range for data of a target memory block of the memory 110 according to the present disclosure to be moved to a preset space may be determined by a determination of the controller 120 performed on the basis of the number of error bits of a weak word line of a weak word line group included in the target memory block and the number of error bits of a strong word line of a strong word line group. The preset space described above may include another memory block included in the memory 110 other than the target memory block.

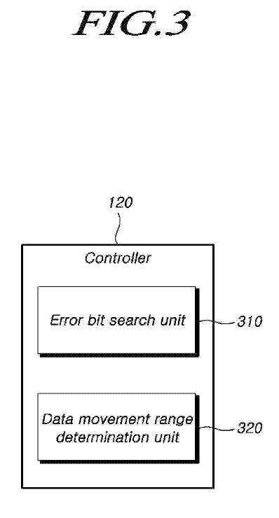

FIG. 3 is a diagram illustrating a schematic configuration of a controller according to embodiments of the present disclosure.

Referring to FIG. 3, a controller 120 of the present disclosure includes an error bit search unit 310 that checks the number of error bits of a word line included in a memory block, and a data movement range determination unit 320 that determines the range of data to be moved within the memory block when a refresh is required, on the basis of the number of error bits of the word line.

The controller 120 of the present disclosure may further include a control circuit and a sub memory.

The controller 120 may control the operation of the memory 110 on the basis of an external command or an internal command. For example, the controller 120 may control an operation of writing data to the memory 110 or an operation of reading written data. Data may be transmitted and received between the controller 120 and the memory 110. Additionally, the controller 120 may control the entirety or a part of data included in the memory 110 to be moved to a preset space. The preset space may include a specific memory block in the memory 110.

Depending on the type of the memory 110, the controller 120 may control a data preservation operation (e.g., a refresh operation or a patrol scrub operation) or an erase operation on data written to the memory 110.

Through the error bit search unit 310, the controller 120 of the present disclosure may check a first number of error bits of a first word line included in a first weak word line group of a target memory block located outside during a first period, and on the basis of a comparison result between the first number of error bits and a preset first reference value, may check a second number of error bits of a second word line included in a strong word line group of the target memory block. Through the data movement range determination unit 320, the controller 120 of the present disclosure may compare the first number of error bits with the first reference value, may compare the difference between the second number of error bits and the first reference value with a preset second reference value, and on the basis of a comparison result between the difference and the second reference value, may set a movement range of data of the target memory block to be moved to a preset space.

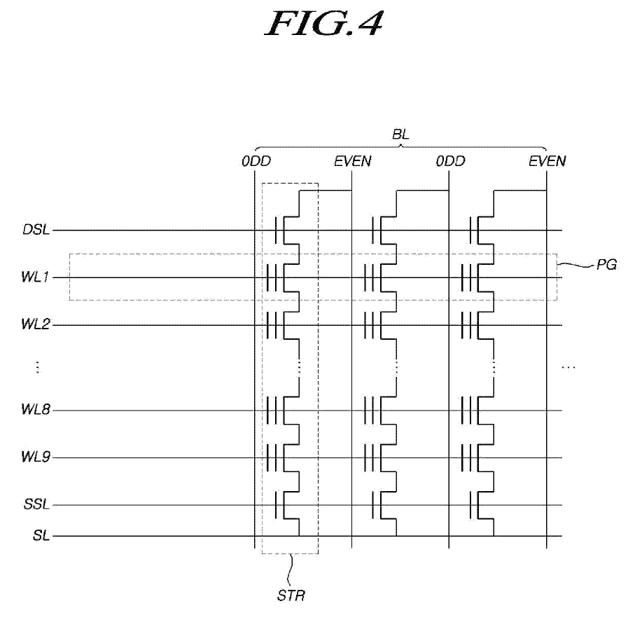

FIG. 4 is a diagram illustrating a configuration of a target memory block on which a refresh operation is executed according to embodiments of the present disclosure.

Referring to FIG. 4, a memory 110 of the present disclosure includes a plurality of memory blocks, and each memory block includes a plurality of word lines and a plurality of bit lines. For the sake of convenience in explanation, the present disclosure will be described using a single memory block as an example.

Recently, many studies have been conducted on ways to increase capacity while reducing the size of NAND memory. In one proposed solution, increasing page size or increasing the number of word lines included in a memory block is considered. However, if capacity increases while the size of NAND memory decreases, a retention phenomenon or a read disturbance phenomenon may occur. In order to solve this problem, the present disclosure proposes measures for detecting the number of error bits for each word line and moving data included in a memory to another space on the basis of the number of error bits. In the present disclosure, moving data included in a memory to another space will be referred to as a refresh.

According to FIG. 4, when a storage device 100 of the present disclosure determines to refresh a target memory block BL, data included in a first word line WL1 to a ninth word line WL9 included in the target memory block may be moved to a preset space. The number of word lines and the refresh range, which is the range of data common to the first through ninth word lines, described above are only examples, and may be set to various numbers or ranges as the occasion demands.

In the present disclosure, a memory block that is the target of a refresh operation because it includes the determined data range for performance of a refresh operation, is referred to as a target memory block BL. As described above, the target memory block may include a plurality of word lines.

As an example, as a method of determining whether a refresh operation is necessary, the storage device 100 of the present disclosure may set a target memory block, may calculate the block read count of the target memory block, and may determine to perform a refresh operation on the entirety of the corresponding target memory block when the block read count is equal to or greater than a preset reference value.

As another example, the storage device 100 of the present disclosure may check the number of error bits for each word line at each predetermined time cycle, and may determine to perform a refresh operation on the entirety of the corresponding target memory block when a greatest number of error bits is equal to or greater than a preset reference value.

As another example, the storage device 100 of the present disclosure may check the number of error bits for each word line at each read cycle of the target memory block, and may determine to perform a refresh operation on the entirety of the corresponding target memory block when a greatest number of error bits is equal to or greater than a preset reference value.

In the present disclosure, the storage device 100 is referred to as a subject that determines whether to perform a refresh operation, but embodiments of the present disclosure are not limited thereto. For example, the controller 120 included in the storage device 100 may be referred to as a subject that determines whether to perform a refresh operation.

In detail, referring to FIG. 4, the memory 110 of the present disclosure may include a core area where memory cells are gathered and a sub area that supports the operation of a memory cell array and that corresponds to the remaining area, other than the core area.

The core area may be composed of pages PG and strings STR. In the core area, a plurality of word lines and a plurality of bit lines may be disposed to intersect each other.

The plurality of word lines may be connected to a separate decoder, and the plurality of bit lines may be connected to a different decoder. Between the plurality of bit lines and the different decoder, there may be a data register corresponding to a read and write circuit.

The plurality of word lines corresponds to a plurality of pages.

The controller 120 included in the storage device 100 of the present disclosure may check the number of error bits of the first word line WL1 to determine whether a refresh operation is necessary.

When the number of error bits of the first word line WL1 of a target memory block is equal to or greater than a preset reference value, the controller 120 of the present disclosure may determine that a refresh operation on the entire target memory block including the first word line WL1 needs to be performed.

When the number of error bits of the first word line WL1 is smaller than the preset reference value, the controller 120 of the present disclosure may check the number of error bits of a second word line WL2 of the target memory block and compare the number of error bits of the second word line WL2 with the preset reference value to determine whether to refresh the target memory block.

The above process may be performed until the number of error bits is checked for all word lines, and the process also may be performed periodically or on demand.

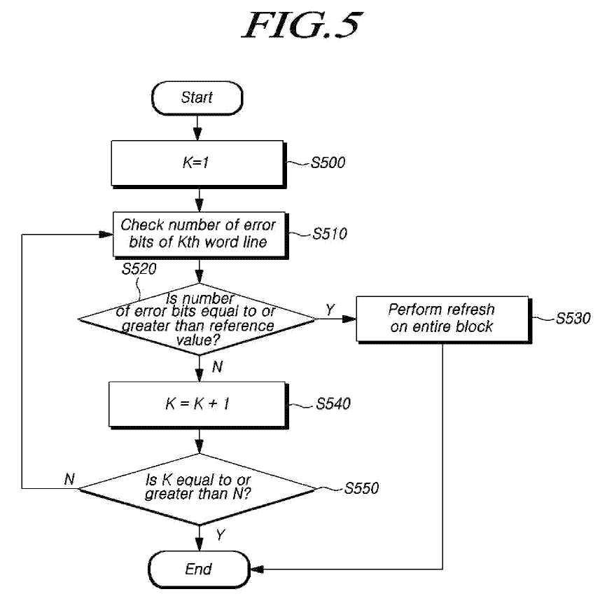

FIG. 5 is a flowchart showing a process of determining whether to perform a refresh operation on a target memory block according to embodiments of the present disclosure.

Referring to FIG. 5, a controller of the present disclosure may determine whether to perform a refresh operation on the entirety of a block while sequentially checking the numbers of error bits of word lines included in the block.

The controller of the present disclosure may initialize a variable K related to the order of word lines included in a memory block (S500).

The controller of the present disclosure may determine a target memory block for determining whether to perform a refresh operation, and may determine the order of word lines for checking the number of error bits. The variable K as an integer equal to or greater than 0 may be initially set to 1.

By initializing the variable K related to the order of the word lines, the controller of the present disclosure may check the number of error bits of a first word line when K=1 (S510).

As described above, each memory block included in a memory may include a plurality of memory cells and a plurality of word lines. Word lines may read data stored in memory cells and store the corresponding data.

An error may occur during the process of a read or write operation on data included in a memory cell, and when the error is detected, a bit where the error has occurred in the memory cell may be set as an error bit. Therefore, errors may exist in data read and stored by a word line in memory cells, and the number of error bits for the corresponding data may be checked by the controller.

When the number of error bits is checked, the controller of the present disclosure may compare the checked number of error bits with a preset reference value, and may check whether the number of error bits is equal to or greater than the preset reference value (S520).

When the number of error bits is equal to or greater than the preset reference value (S520 is Y = yes), it is determined that a refresh operation should be performed on the entire target memory block (S530).

When the number of error bits is smaller than the preset reference value (S520 is N = no), the variable K is incremented by 1 to designate the next word line in the order of the word lines (S540).

This is to check the number of error bits of the next word line set in the word line order.

When the variable K is equal to or greater than a preset number N, it may be determined that checking for error bits for all word lines has ended, and since the number of total error bits is not equal to or greater than the preset reference value, it may be determined that a refresh operation for the target memory block is not necessary (S550).

In S550, N is an integer equal to or greater than 0 and is used to determine whether checking for error bits has been performed for all word lines. N may be set to an integer that is the number of word lines included in the target memory block incremented by 1. For example, when the number of word lines included in the target memory block is 99, the number of word lines is incremented by 1 and N may be set to 100.

When the variable K is smaller than the preset N, the controller of the present disclosure may check the number of error bits for the next word line in the word line order. The controller may compare the number of error bits for the next word line with the preset reference value to determine again at S520 whether to perform a refresh on the target memory block.

The above process may be repeated until checking of the numbers of error bits for all word lines has been completed or when a refresh operation on the entire target memory block is necessary.

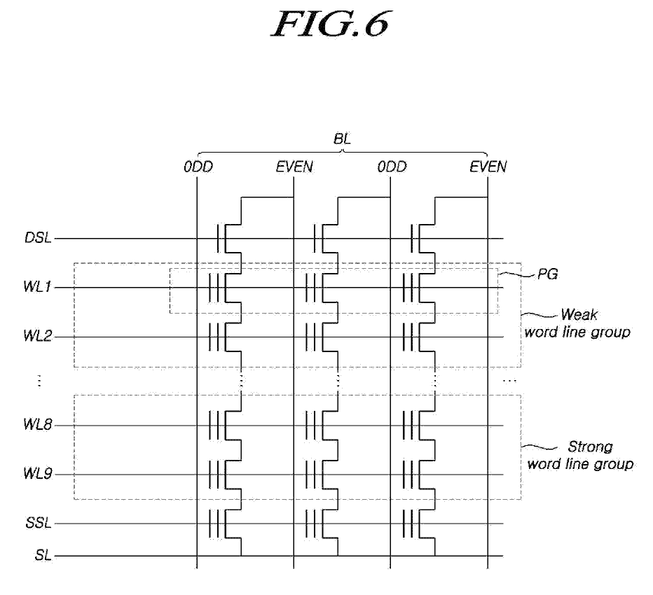

FIG. 6 is a diagram illustrating a configuration of a target memory block on which a refresh operation is executed according to other embodiments of the present disclosure.

Referring to FIG. 6, a memory 110 of the present disclosure may include a plurality of word line groups including a plurality of word lines and a plurality of bit lines.

A word line group may include a preset number of word lines and a preset number of bit lines included in a target memory block.

In the present disclosure, among the word line groups, a word line group that includes word lines totaling a large number of error bits may be referred to as a weak word line group, and a word line group that includes a word line with a small total number of error bits may be referred to as a strong word line group. As described above, each of the number of weak word line groups and the number of strong word line groups is not limited to one, and may be set to a plural number depending on criteria to be set.

In addition, a classification to a weak word line group and a strong word line group is not fixed, and a classification may be changed depending on the numbers of error bits of the word lines in a word line group.

A controller 120 of the present disclosure may determine a range in a memory block that requires a refresh operation, on the basis of the number of error bits of a word line included in each word line group, and may determine that the refresh operation is performed only on the corresponding range. In disclosed embodiments, a range in a memory block may refer to one or more word line groups associated with corresponding memory cells, or to one or more word lines associated with corresponding memory cells. The range of word line groups or word lines associated corresponding data in the memory block that requires a refresh operation is a data movement range. A data movement range may also be a memory block.

As an example, during a first period, the controller 120 of the present disclosure may compare a first error bit number of a first word line included in a first weak word line group of a target memory block during a first period with a preset first reference value. The controller 120 may determine the difference between a second error bit number of a second word line included in a strong word line group of the target memory block with the preset first reference value. The controller 120 may compare the determined difference with a preset second reference value, and may set a movement range of data of the target memory block to be moved to a preset space on the basis of a result of comparing the difference with the second reference value.

As another example, when the first error bit number of the first word line described above is equal to or greater than the first reference value, the controller 120 of the present disclosure may further check a second error bit number of the second word line included in the strong word line group of the target memory block, and may determine the difference between the second error bit number and the first reference value.

As another example, when the difference between the second error bit number and the first reference value is equal to or greater than the second reference value, the controller 120 of the present disclosure may set only the first weak word line group of the target memory block as the data movement range, and may exclude an area other than the first weak word line group of the target memory block from the data movement range.

As another example, during a second period after the first period, in the target memory block, the controller 120 of the present disclosure may check a third error bit number of a third word line included in a second weak word line group other than the first weak word line group. The controller 120 of the present disclosure may not check the number of error bits for an area where a refresh has been performed during any previous period in determining whether to perform a refresh during a next period. In addition, the controller 120 may not check an area on which a refresh is to be performed in the current period. The controller 120 and may exclude these areas from word line groups that are the target of a refresh.

In the present disclosure, an area of the target memory block where a refresh is performed may be referred to as an area in an erased state. The size of an area of the target memory block to be refreshed may be variable, and may vary depending on the state of a memory device.

As another example, when the difference between the second error bit number and the first reference value is smaller than the second reference value, the controller 120 of the present disclosure may set the entire target memory block as a data movement range.

As another example, when the first error bit number is smaller than the first reference value, the controller 120 of the present disclosure may determine to skip a data movement operation on the target memory block during the first period.

As another example, when at least one of the first error bit number of the first word line included in the first weak word line group or the third error bit number of the third word line is equal to or greater than the first reference value, and when the difference between the second error bit number and the first reference value is equal to or greater than the second reference value, the controller 120 of the present disclosure may set the first weak word line group of the target memory block as the data movement range.

As another example, when at least one of the first error bit number of the first word line included in the first weak word line group or a fourth error bit number of a fourth word line included in the second weak word line group is equal to or greater than the first reference value, the controller 120 of the present disclosure may check the second error bit number, and may compare the difference between the second error bit number and the first reference value with the second reference value.

As still another example, when the difference between the second error bit number and the first reference value is equal to or greater than the second reference value, the controller 120 of the present disclosure may set only the first weak word line group and the second weak word line group of the target memory block as the data movement range and may exclude areas other than the first weak word line group and the second weak word line group of the target memory block from the data movement range. When the difference between the second error bit number and the first reference value is smaller than the second reference value, the controller 120 of the present disclosure may set the entire target memory block as the data movement range.

The above-described operations by the controller 120 of the present disclosure may be performed by an error bit search unit 310 or a data movement range determination unit 320 included in the controller 120.

Because a core area, a sub area, pages PG and strings STR of the memory 110 illustrated in FIG. 6 are the same as those of FIG. 4, detailed descriptions thereof will be omitted.

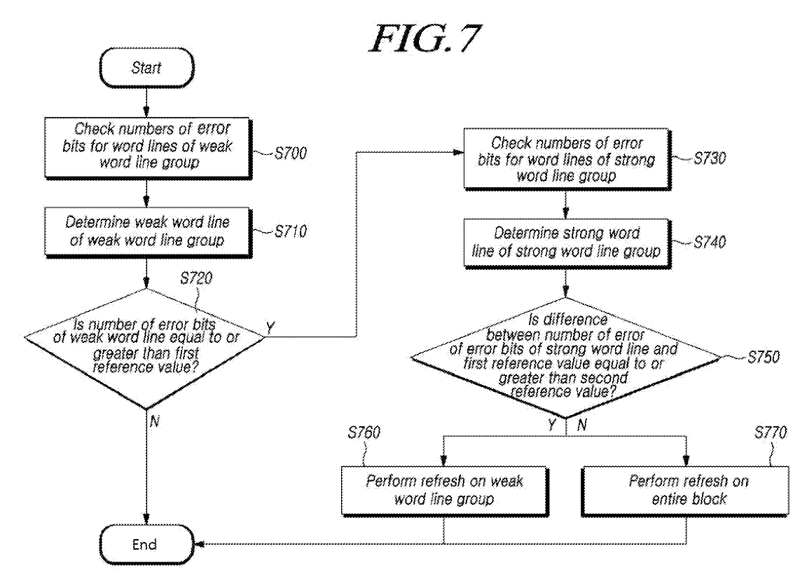

FIG. 7 is a flowchart showing a process of determining a range of a target memory block in which a refresh operation is to be performed according to other embodiments of the present disclosure.

Referring to FIG. 7, a controller of the present disclosure may determine a range in which a refresh operation is to be performed in a target memory block on the basis of the number of error bits for a word line group included in the target memory block.

The controller of the present disclosure checks the numbers of error bits for word lines included in a weak word line group (S700).

As described above, a word line group may include a preset number of word lines, and a weak word line may be determined by checking the numbers of error bits for the word lines.

The controller of the present disclosure determines a word line having a greatest number of error bits among word lines included in the weak word line group as a weak word line (S710).

In the present disclosure, the number of error bits of the above-described word lines may be referred to as the number of error bits of a word line included in the weak word line group or the number of error bits of a weak word line, and similarly, the number of error bits for a word line having fewest number of error bits among the numbers of error bits of word lines included in a strong word line group may be referred to as the number of error bits of a word line included in the strong word line group or the number of error bits of a strong word line.

When the number of error bits of the weak word line is checked, the controller of the present disclosure compares the number of error bits of the weak word line with a preset first reference value to check whether the number of error bits of the weak word line is equal to or greater than the preset first reference value (S720).

When the number of error bits of the word line included in the weak word line group is not equal to or greater than the preset first reference value, the controller of the present disclosure determines that a refresh operation for the memory block including the weak word line group is not necessary, skips a refresh on the corresponding target memory block, and performs a determination on whether to refresh a next target memory block.

When the number of error bits of the word line included in the weak word line group is equal to or greater than the preset first reference value, the controller of the present disclosure checks the numbers of error bits for word lines included in a strong word line group (S730).

The controller of the present disclosure determines a strong word line on the basis of the numbers of error bits of the respective word lines included in the strong word line group (S740).

When the strong word line is determined, the controller of the present disclosure determines the difference between the number of error bits of the strong word line and the first reference value, and compares the corresponding that determined difference with a second reference value to determine whether the difference is equal to or greater than the second reference value (S750).

When the above-described difference is equal to or greater than the second reference value, the controller of the present disclosure limits a range of performing a refresh to the weak word line group (S760).

On the other hand, when the above-described difference is smaller than the second reference value, the controller of the present disclosure determines a range of performing a refresh as the entire target memory block (S770).

In the present disclosure, whether a refresh is required for the target memory block is determined on the basis of the numbers of error bits of the respective word lines included in the weak word line group, and when it is determined that a refresh is required, a range of performing a refresh is determined for the entirety or a part of the target memory block on the basis of the numbers of error bits of the respective word lines included in the strong word line group, whereby it is possible to prevent a refresh operation from being performed on a memory area that does not require a refresh operation.

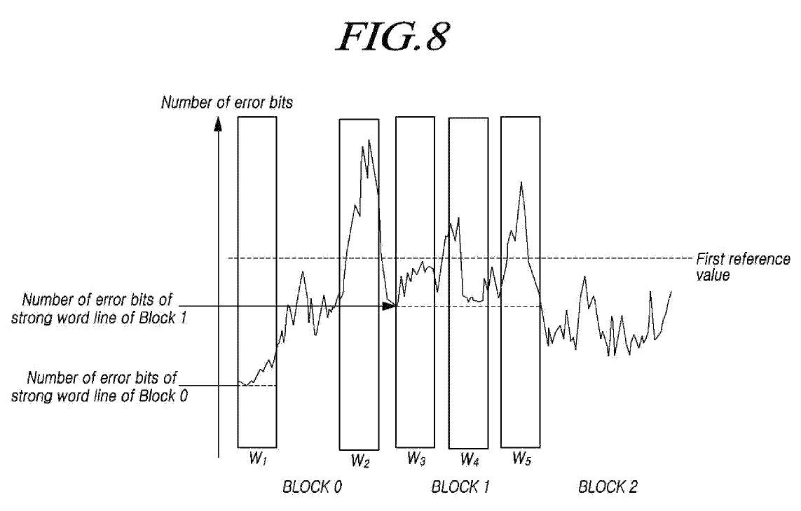

FIG. 8 is a diagram showing a refresh operation performed on a target memory block according to further embodiments of the present disclosure.

Referring to FIG. 8, a memory device of the present disclosure may include a plurality of memory blocks, and each memory block may include a plurality of word line groups.

For example, as illustrated in FIG. 8, a memory device may include memory blocks including BLOCK0, BLOCK1 and BLOCK2. The memory device may include a strong word line group W1 and a weak word line group W2 as in BLOCK0, may include a strong word line group W3 and two word line groups W4 and W5 having word lines with error bits equal to or greater than a first reference value as in BLOCK1, and may include a word line group having only word lines with error bits smaller than the first reference value as in BLOCK2.

In the present disclosure, a part corresponding to a number of error bits greater than numbers of error bits of surrounding word lines within each word line group may be referred to as a peak. The point where the rate of change of the number of error bits changes sharply can be called a peak. For example, the word line group W2 has two peaks, and the word line group W5 has one peak.

For example, when there are two peaks as in the weak word line group W2 of BLOCK0 among the memory blocks of the memory device of FIG. 8 and at least one of the two peaks is equal to or greater than the first reference value, the difference between the number of error bits of a strong word line included in the strong word line group and the first reference value is compared with a second reference value, and when the difference is equal to or greater than the second reference value, only the weak word line group of the target memory block may be set as a data movement range.

That is to say, the controller of the present disclosure does not determine to refresh the entire block immediately even when at least one of the two peaks is equal to or greater than the first reference value, but instead may determine an area where a refresh is to be performed on the basis of the number of error bits of the strong word line included in the strong word line group.

Therefore, when at least one of the number of error bits of one word line included in the weak word line group and the number of error bits of another word line is equal to or greater than the first reference value, and the difference between the number of error bits of the word line included in the strong word line group and the first reference value is equal to or greater than the preset second reference value, the controller of the present disclosure may set only the weak word line group included in the target memory block as a data movement range in which a refresh operation is to be performed.

On the other hand, when at least one of the number of error bits of one word line included in the weak word line group and the number of error bits of another word line is equal to or greater than the first reference value, and the difference between the number of error bits of the word line included in the strong word line group and the first reference value is smaller than the preset second reference value, the controller of the present disclosure may set the entire target memory block as a data movement range in which a refresh operation is to be performed.

As another example, as in BLOCK1 among the memory blocks of the memory device of FIG. 8, at least two weak word line groups may exist in one target memory block. In this case, when at least one of the number of error bits of a word line included in a fourth weak word line group W4 or the number of error bits of a word line included in a fifth weak word line group W5 is equal to or greater than the first reference value, the controller of the present disclosure may check the number of error bits of a third strong word line group W3, and may compare the difference between the number of error bits of the third strong word line group W3 and the first reference value with the second reference value.

In the case of BLOCK1 described above, when the difference between the number of error bits of the third strong word line group W3 and the first reference value is equal to or greater than the second reference value, the controller of the present disclosure may set only the fourth weak word line group and the fifth weak word line group of the target memory block as a data movement range, and when the difference is smaller than the second reference value, the controller of the present disclosure may set the entire target memory block as a data movement range.

Accordingly, when at least one of the numbers of error bits of respective weak word lines of at least two weak word line groups is equal to or greater than the first reference value, the controller of the present disclosure may not immediately determine to perform a refresh on the entire target memory block, but may determine a range in which a refresh is to be performed on the basis of the number of error bits of the word line included in the strong word line group.

As still another example, as in BLOCK2 among the memory blocks of the memory device of FIG. 8, a word line group including a word line equal to or greater than the first reference value may not exist. In this case, the controller of the present disclosure may determine that a refresh operation on the entire memory block is not necessary.

Although various embodiments of the present disclosure have been described with particular specifics and varying details for illustrative purposes, those skilled in the art will appreciate that various modifications, additions and substitutions may be made based on what is disclosed or illustrated in the present disclosure without departing from the spirit and scope of the present disclosure as defined in the following claims.

What is claimed is:

1. A storage device comprising:
a memory including a plurality of memory blocks, each of which includes a plurality of word lines; and
a controller configured to compare a first error bit number of a first word line included in a first weak word line group of a target memory block during a first period with a preset first reference value, compare the difference between a second error bit number of a second word line included in a strong word line group of the target memory block and the first reference value with a preset second reference value, set a movement range of data of the target memory block on the basis of a result of comparing the difference with the second reference value,
wherein the controller selects a preset space in the memory and moves the data to the preset space.

2. The storage device according to claim 1, wherein, when the first error bit number of the first word line is equal to or greater than the first reference value, the controller checks the second error bit number of the second word line included in the strong word line group of the target memory block, and
determines the difference between the second error bit number and the first reference value.

3. The storage device according to claim 1, wherein, when the difference between the second error bit number and the first reference value is equal to or greater than the second reference value, the controller sets only the first weak word line group of the target memory block as the data movement range, and excludes an area other than the first weak word line group of the target memory block from the data movement range.

4. The storage device according to claim 3, wherein, during a second period after the first period, in the target memory block the controller checks a third error bit number of a third word line included in a second weak word line group other than the first weak word line group.

5. The storage device according to claim 1, wherein, when the difference between the second error bit number and the first reference value is smaller than the second reference value, the controller sets the entire target memory block as the data movement range.

6. The storage device according to claim 1, wherein, when the first error bit number is smaller than the first reference value, the controller skips a data movement operation on the target memory block during the first period.

7. The storage device according to claim 1, wherein, when at least one of the first error bit number of the first word line included in the first weak word line group or the third error bit number of the third word line is equal to or greater than the first reference value, and the difference between the second error bit number and the first reference value is equal to or greater than the second reference value, the controller sets only the first weak word line group of the target memory block as the data movement range, and excludes an area other than the first weak word line group of the target memory block from the data movement range.

8. The storage device according to claim 1, wherein, when at least one of the first error bit number of the first word line included in the first weak word line group or a fourth error bit number of a fourth word line included in the second weak word line group is equal to or greater than the first reference value, the controller checks the second error bit number, and compares the difference between the second error bit number and the first reference value with the second reference value.

9. The storage device according to claim 8, wherein
when the difference between the second error bit number and the first reference value is equal to or greater than the second reference value, the controller sets only the first weak word line group and the second weak word line group of the target memory block as the data movement range, and excludes an area other than the first weak word line group and the second weak word line group of the target memory block from the data movement range, and
when the difference between the second error bit number and the first reference value is smaller than the second reference value, the controller sets the entire target memory block as the data movement range.

10. A memory device comprising:
a first memory block including a target memory block that includes a first weak word line group and a strong word line group; and
a second memory block to which data of the target memory block is to be moved,
wherein a movement range for the data of the target memory block that is moved from the first memory block to the second memory block is set on the basis of a first comparison result in which a first error bit number of a first word line included in the first weak word line group of the target memory block during a first period is compared with a preset first reference value and on the basis of a second comparison result in which the difference between a second error bit number of a second word line included in the strong word line group of the target memory block and the first reference value is compared with a preset second reference value.

11. The memory device according to claim 10, wherein, when the difference between the second error bit number and the first reference value is equal to or greater than the second reference value, only the first weak word line group of the target memory block is set as the data movement range, and an area other than the first weak word line group of the target memory block is excluded from the data movement range.

12. The memory device according to claim 10, wherein, when the difference between the second error bit number and the first reference value is smaller than the second reference value, the entire target memory block is set as the data movement range.

13. The memory device according to claim 10, wherein, when the first error bit number is smaller than the first reference value, it is determined to skip a data movement operation on the target memory block during the first period.

14. The memory device according to claim 10, wherein, when at least one of the first error bit number of the first word line included in the first weak word line group or a third error bit number of a third word line is equal to or greater than the first reference value and the difference between the second error bit number and the first reference value is equal to or greater than the second reference value, the first weak word line group of the target memory block is set as the data movement range.

15. A controller comprising:
an error bit search unit configured to check a first error bit number of a first word line included in a first weak word line group of a target memory block located outside during a first period, and check, on the basis of a comparison result between the first error bit number and a preset first reference value, a second error bit number of a second word line included in a strong word line group of the target memory block; and
a movement range determination unit configured to compare the first error bit number with the first reference value, compare the difference between the second error bit number and the first reference value with a preset second reference value, and set, on the basis of a comparison result between the difference and the second reference value, a movement range of data of the target memory block,
wherein the controller selects a preset space in a memory including the target memory block and moves the data to the preset space.

16. The controller according to claim 15, wherein the movement range determination unit
when the first error bit number of the first word line is equal to or greater than the first reference value, checks the second error bit number of the second word line included in the strong word line group of the target memory block, and
determines the difference between the second error bit number and the first reference value.

17. The controller according to claim 15, wherein, when the difference between the second error bit number and the first reference value is equal to or greater than the second reference value, the movement range determination unit sets only the first weak word line group of the target memory block as the data movement range, and excludes an area other than the first weak word line group of the target memory block from the data movement range.

18. The controller according to claim 15, wherein, during a second period after the first period, the movement range determination unit checks a third error bit number of a third word line included in a second weak word line group other than the first weak word line group in the target memory block.

19. The controller according to claim 15, wherein, when the difference between the second error bit number and the first reference value is smaller than the second reference value, the movement range determination unit sets the entire target memory block as the data movement range.

20. The controller according to claim 15, wherein, when the first error bit number is smaller than the first reference value, the movement range determination unit skips a data movement operation on the target memory block during the first period.
